(19) United States
(12) Patent Application Publication
(10) Pub. No.: US 2017/0254459 A1
(43) Pub. Date: Sep. 7, 2017

(54) PIPE CONNECTOR AND ELECTRONIC DEVICE

(71) Applicant: COOLER MASTER CO., LTD., New Taipei City (TW)

(72) Inventor: Hsin-Hung CHEN, New Taipei City (TW)

(21) Appl. No.: 15/203,018

(22) Filed: Jul. 6, 2016

(30) Foreign Application Priority Data
Mar. 3, 2016 (CN) 201620163330.7

(51) Int. Cl. F16L 37/084; H05K 7/20

(52) U.S. Cl. CPC F16L 37/084; H05K 7/20218

(57) ABSTRACT

A pipe connector for connecting with an additional pipe connector includes a first leak-proof pipe, a first sleeve, at least one clamping element and a restricting structure. The first sleeve covers the first leak-proof pipe and allows the first leak-proof pipe to relatively slide therein. The clamping element and the restricting structure are disposed on the first sleeve. The restricting structure is capable of driving the clamping element to clamp or release the additional pipe connector at different positions.

### CROSS REFERENCE TO RELATED APPLICATIONS

This Non-provisional application claims priority under 35 U.S.C. §119(a) on Patent Application No(s). 201620163330.7 filed in People's Republic of China on Mar. 3, 2016, the entire contents of which are hereby incorporated by reference.

### BACKGROUND OF THE INVENTION

Field of Invention

The present invention relates to a pipe connector and an electronic device having the pipe connector.

Related Art

The conventional heat-dissipating systems include an air-cooling type heat-dissipating device or a water-cooling type heat-dissipating device. The water-cooling type heat-dissipating device includes a pump, a water tank, water-cooling pipes and pipe connectors, which are assembled to form a cyclic loop. After being used for a long time, the components may need to be replaced or the water tank should be refilled. These repairing procedures must be carefully performed with preventing the leakage of water.

In addition, the replacement of the conventional pipe connector usually needs two hands of the user. If the water-cooling system is installed in a narrower space, it will be difficult to replace the pipe connector.

### SUMMARY OF THE INVENTION

An objective of the present invention is to provide a pipe connector that can be easily replaced, and an electronic device containing the pipe connector.

The present invention discloses a pipe connector for connecting with an additional pipe connector. The pipe connector includes a first leak-proof pipe, a first sleeve, at least a clamping element and a restricting structure. The first sleeve covers the first leak-proof pipe and allows the first leak-proof pipe to relatively slide in the first sleeve. The clamping element and the restricting structure are disposed on the first sleeve. The restricting structure is capable of driving the clamping element to clamp or release the additional pipe connector at different positions.

In one embodiment, the first sleeve comprises at least a through hole penetrating through inner and outer wall surfaces of the first sleeve, and the clamping element is disposed in the through hole.

In one embodiment, the restricting structure is slidingly disposed on the first sleeve and includes a concave portion and a protruding portion. The concave portion is configured for accommodating the clamping element so as to release the additional pipe connector. The protruding portion is configured for pushing the clamping element toward an inside portion of the first sleeve so as to clamp the additional pipe connector.

In one embodiment, the restricting structure further includes a sleeve body and a pushing rod. The concave portion and the protruding portion are disposed in the sleeve body, and the pushing rod has one end contacting against the sleeve body. When the protruding portion pushes the clamping element toward the inside portion of the first sleeve, the pushing rod is pushed to move the sleeve body with relative to the first sleeve, and the concave portion receives the clamping element so as to release the additional pipe connector.

In one embodiment, the clamping element is a ball, which is restricted within the through hole by the restricting element.

In one embodiment, the first sleeve includes a front-end pipe body and a middle pipe body. The front-end pipe body has a first inner diameter, and the middle pipe body has a second inner diameter. The through hole is formed on the front-end pipe body. The middle pipe body is located at a deeper part of the first sleeve than the front-end pipe body. The first inner diameter is larger than the second inner diameter, and the second inner diameter matches with an outer diameter of the additional pipe connector. The front-end pipe body and the middle pipe body have chambers for accommodating the additional pipe connector.

In one embodiment, the pipe connector further includes an elastic element and a stop ring. The elastic element has two ends connecting to the first sleeve and the restricting structure, respectively. The stop ring is disposed near to an opening of the first sleeve for preventing the restricting structure from leaving the first sleeve.

In one embodiment, the additional pipe connector includes a second sleeve and a second leak-proof pipe. The second sleeve is inserted into the first sleeve along an axial direction of the first sleeve. The first leak-proof pipe is contact against the second leak-proof pipe and then the second sleeve is inserted into a deeper place of the first sleeve until the clamping element clamps the second sleeve. When the clamping element clamps the second sleeve, the restricting structure is pushed along the axial direction so as to make the clamping element to release the second sleeve.

The present invention also discloses a pipe connector including a second leak-proof pipe and a second sleeve. The second sleeve covers the second leak-proof pipe and allows the second leak-proof pipe to relatively slide in the second sleeve. In addition, the second sleeve includes a wedged portion disposed on the second sleeve for locking with a clamping element.

In one embodiment, the second sleeve further includes a front-end pipe body and a middle pipe body. The front-end pipe body has a first inner diameter, and the middle pipe body has a second inner diameter. The front-end pipe body includes a leak-proof protruding portion, which is formed close to an inner opening of the front-end pipe body. The first inner diameter is smaller than the second inner diameter, and the wedged portion is disposed at outside of the middle pipe body.

The present invention further discloses an electronic device containing the above pipe connector.

As mentioned above, the pipe connector of the invention includes a first leak-proof pipe, a first sleeve, at least one clamping element and a restricting structure. Accordingly, the user can easily push the restricting structure to release the clamping element by a single hand, thereby achieving the goal of easily replacement of the components of the electronic device. Moreover, if the electronic device is installed in a narrower space, the pipe connector of the invention is still easily replaced by a single hand.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic diagram of a pipe connector according to a preferred embodiment of the invention;

FIG. 1B is an exploded view of the pipe connector of FIG. 1A;

FIG. 2A and FIG. 2B are sectional views showing two pipe connectors of FIG. 1A, which are connected to each other;

FIG. 2C is a sectional view showing two pipe connectors, which are disconnected; and

FIG. 3 is a schematic diagram of an electronic device containing the pipe connector according to a preferred embodiment of the invention.

### DETAILED DESCRIPTION OF THE INVENTION

The present invention will be apparent from the following detailed description, which proceeds with reference to the accompanying drawings, wherein the same references relate to the same elements.

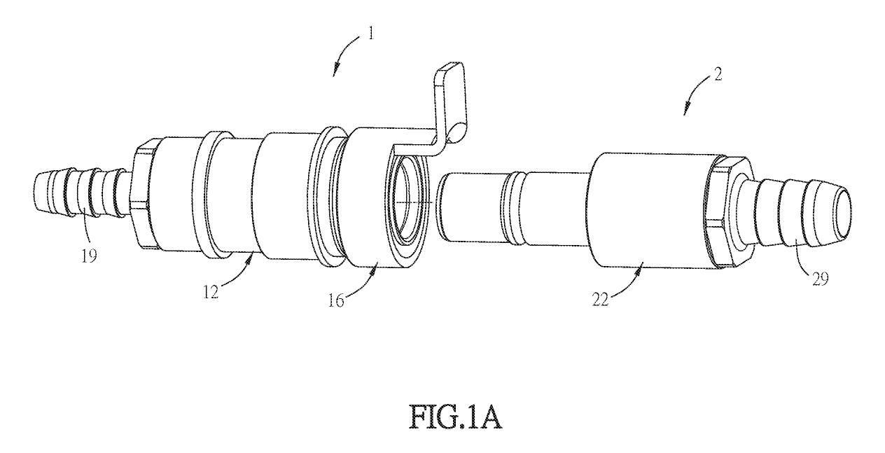

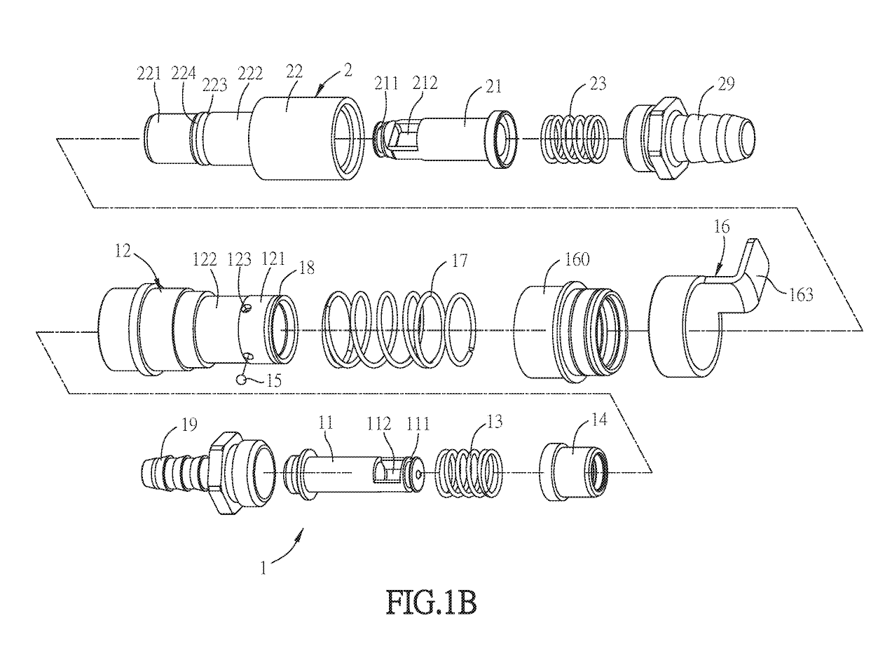

FIG. 1A is a schematic diagram of a pipe connector according to a preferred embodiment of the invention, and FIG. 1B is an exploded view of the pipe connector of FIG. 1A.

Referring to FIGS. 1A and 1B, a first pipe connector 1 is configured to connect with a second pipe connector 2. The first pipe connector 1 includes a first leak-proof pipe 11, a first sleeve 12, an elastic element 13, a contacting pipe 14, a clamping element 15, a restricting structure 16, an elastic element 17, a stop ring 18 and a first pipe 19.

The first sleeve 12 includes a first front-end pipe body 121 and a first middle pipe body 122. The internal chambers of the pipe bodies 121 and 122 are configured to receive the second pipe connector 2. The first front-end pipe body 121 has a first inner diameter d1, and the first middle pipe body 122 has a second inner diameter d2, which is different from the first inner diameter d1. The first middle pipe body 122 is located at a deeper part of the first sleeve 12 than the first front-end pipe body 121. The first inner diameter d1 is larger than the second inner diameter d2, and the second inner diameter d2 matches with an outer diameter of the second pipe connector 2. The first sleeve 12 includes at least one through hole 123, which penetrates through the inner and outer wall surfaces of the first sleeve 12. The clamping element 15 is disposed in the through hole 123. In this embodiment, the first front-end pipe body 121 is configured with a plurality of through holes 123 for accommodating multiple clamping elements 15. The clamping element 15 is a ball, which is restricted within the through hole 123 by the restricting structure 16.

The elastic element 17, the restricting structure 16 and the stop ring 18 are installed on the first sleeve 12. The restricting structure 16 is slidingly disposed on the first sleeve 12. The elastic element 17 has two ends connecting to the first sleeve 12 and the restricting structure 16, respectively. The stop ring 18 is disposed near to an opening of the first sleeve 12 for preventing the restricting structure 16 from leaving the first sleeve 12. After assembling these components, the elastic element 17 is slightly compressed so as to apply a force to the restricting structure 16, so that the restricting structure 16 is pushed to contact against the stop ring 18, which is disposed on the outer wall edge of the first front-end pipe body 121.

The restricting structure 16 includes a sleeve body 160 and a pushing rod 163. One end of the pushing rod 163 contacts against the sleeve body 160. The inner edge of the sleeve body 160 is configured with a concave portion 161 and a protruding portion 162. The protruding portion 162 is configured to push the clamping element 15 into the first sleeve 12 so as to clamp the second pipe connector 2. The concave portion 161 is configured to accommodate the clamping element 15 so as to release the second pipe connector 2. When the protruding portion 162 pushes the clamping element 15 toward the inside portion of the first sleeve 12, the pushing rod 163 is pushed to move the sleeve body 160 with relative to the first sleeve 12, and the concave portion 161 receives the clamping element 15 so as to release the second pipe connector 2.

The first sleeve 12 has a first chamber 120, and the contacting pipe 14, the elastic element 13 and the first leak-proof pipe 11 are sequentially disposed in the first chamber 120. The first sleeve 12 covers the first leak-proof pipe 11 and allows the first leak-proof pipe 11 to relatively slide in the first sleeve 12. The clamping element 15 and the restricting structure 16 are disposed on the first sleeve 12. The restricting structure 16 is capable of driving the clamping element 15 to clamp or release the second pipe connector 2 at different positions. The first leak-proof pipe 11 has a first end portion 111 and a first hole 112 through which the liquid and the second pipe connector 2 are flowing. The tail portions of the first sleeve 12 and the first leak-proof pipe 11 are connected to the first pipe 19, and the first pipe 19 is further connected to the pipe. After assembling these components, the elastic element 13 is compressed so as to apply a force to push the contacting pipe 14 outwardly, so that the first end portion 111 is even with the contacting pipe 14 so as to block the flowing fluid.

The second pipe connector 2 includes a second leak-proof pipe 21, a second sleeve 22 and an elastic element 23. The second sleeve 22 includes a second front-end pipe body 221 and a second middle pipe body 222. The second front-end pipe body 221 has a first inner diameter D1, and the second middle pipe body 222 has a second inner diameter D2, which is different from the first inner diameter D1. The first inner diameter D1 is smaller than the second inner diameter D2. The second front-end pipe body 221 includes a leak-proof protruding portion 224, which is disposed near to the inner opening of the second front-end pipe body 221. A wedged portion 223 is disposed at outside of the second middle pipe body 222 and is configured for being clamped by the clamping element 15 of the first pipe connector 1.

The second sleeve 22 has a second chamber 220, and the second leak-proof pipe 21 and the elastic element 23 are sequentially disposed in the second chamber 220. The second sleeve 22 covers the second leak-proof pipe 21 and allows the second leak-proof pipe 21 to relatively slide in the second sleeve 22. The second leak-proof pipe 21 has a second end portion 211 and a second hole 212 through which the liquid and the first pipe connector 1 are flowing. The tail portions of the second sleeve 22 and the second leak-proof pipe 21 are connected to the second pipe 29, and the second pipe 29 is further connected to the pipe. After assembling these components, the second end portion 211 is even with the opening of the second sleeve 22 so as to block the flowing fluid.

In addition, the pip connector and the pipe can be connected by screwing, locking, wedging or adhering, and this invention is not limited.

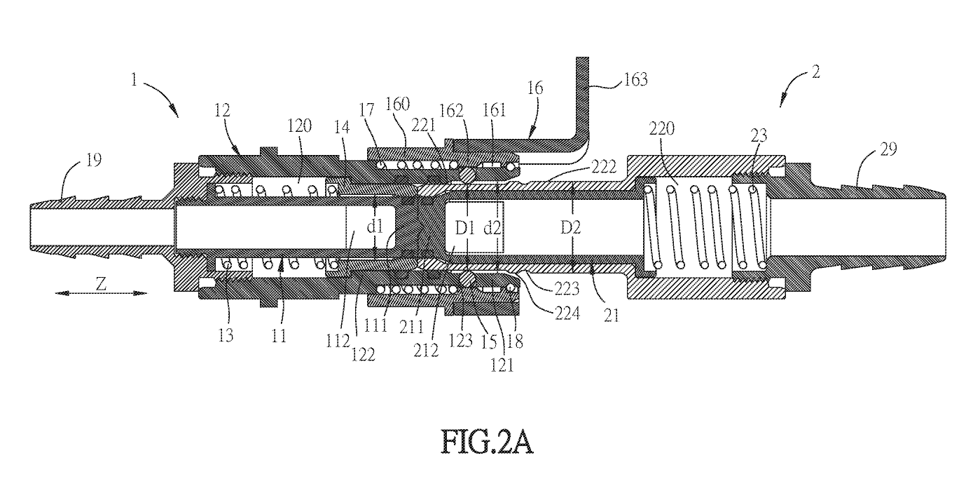

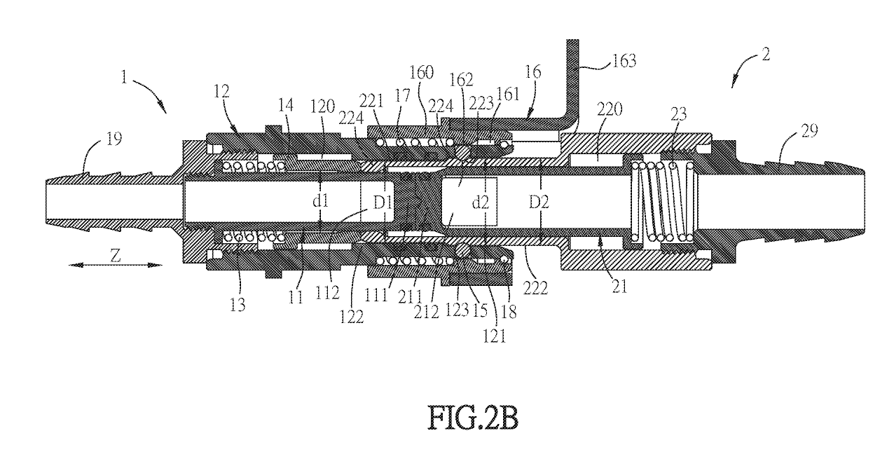

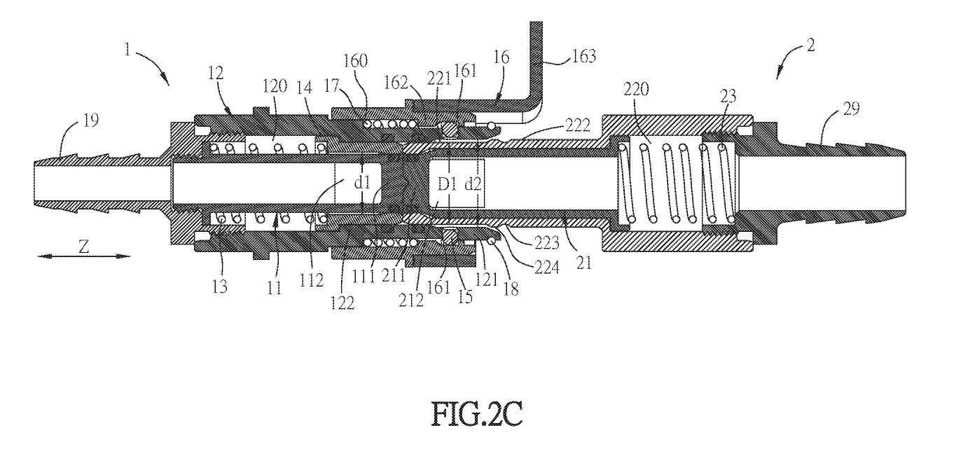

FIG. 2A and FIG. 2B are sectional views showing two pipe connectors 1 and 2 of FIG. 1A, which are connected to each other. As shown in FIG. 2A, when the second pipe connector 2 is inserted into the first pipe connector 1, the first end portion 11 and the second end portion 211 will contact with each other at the beginning. At this moment, the first leak-proof pipe 11 is still not inserted deep into the second sleeve 22 yet. That is, the first leak-proof pipe 11 and the second leak-proof pipe 21 are not communicated with each other yet. In addition, since the second sleeve 22 is still not inserted deep in, the clamping element 15 is still not clamped with the wedged portion 223 yet.

As shown in FIG. 2B, after inserting the second pipe connector 2 into the first pipe connector 1 (see FIG. 2A), the tail portion of the first leak-proof pipe 11 is fixed on the first pipe 19, so that the second leak-proof pipe 21 cannot go deeper anymore, and only the second sleeve 22 can move to the deeper place of the first pipe connector 1. In this case, the contacting pipe 14 also moves inwardly so as to press the elastic element 13. After reaching the clamping position, one end of the clamping element 15 is locked with the wedged portion 223, and the other end of the clamping element 15 is pressed by the protruding portion 162. Thus, the second sleeve 22 is clamped by the restricting structure 16 and the clamping element 15, and it cannot move freely. Besides, the front end of the first leak-proof pipe 11 enters the second chamber 220, so that the fluid can flow through the first hole 112 and the second hole 212, thereby finishing the connection and communication of the first pipe connector 1 and the second pipe connector 2.

FIG. 2C is a sectional view showing two pipe connectors, which are disconnected. As shown in FIG. 2C, in order to disconnect the first pipe connector 1 and the second pipe connector 2, the user can press the pushing rod 163 to release the first pipe connector 1 from the clamping element 15, and then pull the second pipe connector 2 from the first pipe connector 1 by a single hand.

With reference to FIG. 2C, when the pushing rod 163 is pressed, the sleeve body 160 also moves toward the tail end of the second sleeve pipe 22 until that the concave portion 161 is aligned with the wedged portion 223, so that the clamping element 15 can move to the concave portion 161 and does not clamp the first pipe connector 1. In this case, since the elastic element 13 is compressed, it can apply a force to push the second pipe connector 2 out of the first pipe connector 1. At the same time, the elastic element 13 can also apply a force to move the pushing rod 163 back its original position.

As shown in FIGS. 2A to 2C, the second sleeve 22 is inserted into the first sleeve 12 along an axial direction Z of the first sleeve 12. After the first leak-proof pipe 11 contacts against the second leak-proof pipe 21, the second sleeve 22 is inserted into the deeper place of the first sleeve 12 until that the clamping element 15 clamps the second sleeve 22. When the clamping element 15 clamps the second sleeve 22, the restricting structure 16 can be pushed and move along the axial direction Z so as to release the second sleeve 22 from the clamping element 15.

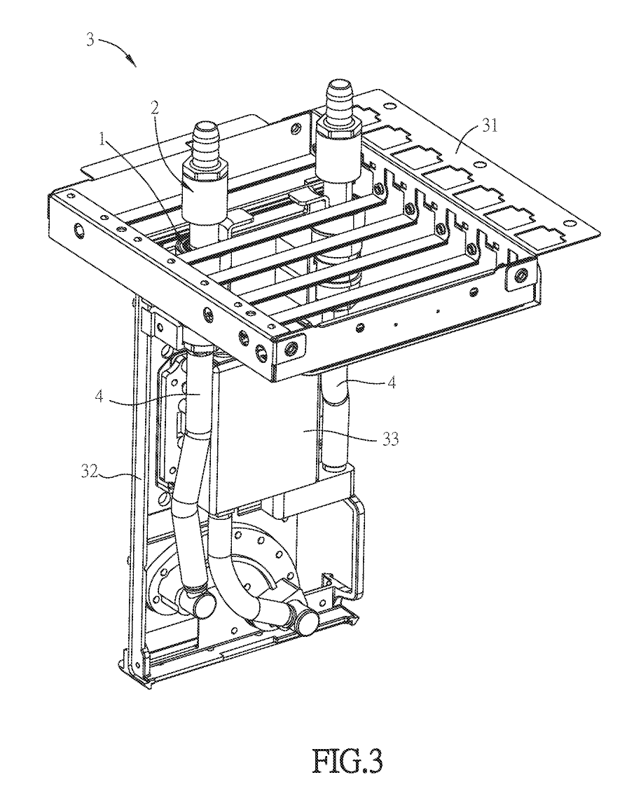

FIG. 3 is a schematic diagram of an electronic device 3 containing the pipe connectors 1 and 2. The electronic device 3, such as a computer, includes a frame 31, an interface card 32 and a heat sink 33. The interface card 32 is fixed on the frame 31, and the heat sink 33 is installed on the interface card 32. The pipe 4 is connected to the first pipe connector 1 and the second pipe connector 2, and passes through the heat sink 33. A pump is connected to the pipe, so that the fluid can be pumped and flow in the pipe so as to provide the desired heat-dissipating effect. In order to make the description easier and clearer, FIG. 3 only shows a part of the frame 31 and other components. For example, a part of the pipe, which is located outside of the frame 31 and connected to the second pipe connector 2, is not shown in FIG. 3. In addition, since the inner diameter of the second middle pipe body 222 is narrower, it is possible to use the second middle pipe body 222 to fix the pipe in the opening of the frame 31.

In summary, the user can easily push the restricting structure by a single hand to release the clamping element, and then disconnect the connectors, thereby achieving the goal of easily replacement of the components of the electronic device in a narrower space. For example, if the restricting structure is configured on a female connector and the male connector is inserted into the female connector, the user can press the restricting structure to release the male connector from the female connector, and then depart the male connector from the female connector by the same hand.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A pipe connector for connecting with an additional pipe connector, the pipe connector comprising:
a first leak-proof pipe;
a first sleeve covering the first leak-proof pipe and allowing the first leak-proof pipe to relatively slide in the first sleeve;
at least a clamping element disposed on the first sleeve; and
a restricting structure disposed on the first sleeve, wherein the restricting structure is capable of driving the clamping element to clamp or release the additional pipe connector at different positions.

2. The pipe connector according to claim 1, wherein the first sleeve comprises at least a through hole penetrating through inner and outer wall surfaces of the first sleeve, and the clamping element is disposed in the through hole.

3. The pipe connector according to claim 2, wherein the restricting structure is slidingly disposed on the first sleeve and comprises:
a concave portion configured for accommodating the clamping element so as to release the additional pipe connector; and
a protruding portion configured for pushing the clamping element toward an inside portion of the first sleeve so as to clamp the additional pipe connector.

4. The pipe connector according to claim 3, wherein the restricting structure further comprises:
a sleeve body, wherein the concave portion and the protruding portion are disposed in the sleeve body; and
a pushing rod having one end contacting against the sleeve body;
wherein when the protruding portion pushes the clamping element toward the inside portion of the first sleeve, the pushing rod is pushed to move the sleeve body with relative to the first sleeve, and the concave portion receives the clamping element so as to release the additional connector.

5. The pipe connector according to claim 2, wherein the clamping element is a ball, which is restricted within the through hole by the restricting element.

6. The pipe connector according to claim 2, wherein the first sleeve comprises:
a front-end pipe body having a first inner diameter, wherein the through hole is formed on the front-end pipe body; and
a middle pipe body having a second inner diameter, wherein the middle pipe body is located at a deeper part of the first sleeve than the front-end pipe body, the first inner diameter is larger than the second inner diameter, the second inner diameter matches with an outer diameter of the additional pipe connector, and the front-end pipe body and the middle pipe body have chambers for accommodating the additional pipe connector.

7. The pipe connector according to claim 1, further comprising:
an elastic element having two ends connecting to the first sleeve and the restricting structure, respectively; and
a stop ring disposed near to an opening of the first sleeve for preventing the restricting structure from leaving the first sleeve.

8. The pipe connector according to claim 1, wherein the additional pipe connector comprises a second sleeve and a second leak-proof pipe;
wherein the second sleeve is inserted into the first sleeve along an axial direction of the first sleeve;
wherein the first leak-proof pipe is contact against the second leak-proof pipe and then the second sleeve is inserted into a deeper place of the first sleeve until the clamping element clamps the second sleeve; and
wherein when the clamping element clamps the second sleeve, the restricting structure is pushed along the axial direction so as to make the clamping element to release the second sleeve.

9. A pipe connector, comprising:
a second leak-proof pipe; and
a second sleeve covering the second leak-proof pipe and allowing the second leak-proof pipe to relatively slide in the second sleeve, wherein the second sleeve comprises:
a wedged portion disposed on the second sleeve for locking with a clamping element of an additional pipe connector;
wherein the additional pipe connector comprises:
a first leak-proof pipe;
a first sleeve covering the first leak-proof pipe and allowing the first leak-proof pipe to relatively slide in the first sleeve, wherein the clamping element is disposed on the first sleeve; and
a restricting structure disposed on the first sleeve, wherein the restricting structure is capable of driving the clamping element to clamp or release the pipe connector at different positions.

10. The pipe connector according to claim 9, wherein the second sleeve further comprises:
a front-end pipe body having a first inner diameter and comprising a leak-proof protruding portion, wherein the leak-proof protruding portion is formed close to an inner opening of the front-end pipe body; and
a middle pipe body having a second inner diameter, wherein the first inner diameter is smaller than the second inner diameter, and the wedged portion is disposed at outside of the middle pipe body.

11. An electronic device have a pipe connector for connecting with an additional pipe connector, the pipe connector comprising:
a first leak-proof pipe;
a first sleeve covering the first leak-proof pipe and allowing the first leak-proof pipe to relatively slide in the first sleeve;
at least a clamping element disposed on the first sleeve; and
a restricting structure disposed on the first sleeve, wherein the restricting structure is capable of driving the clamping element to clamp or release the additional pipe connector at different positions.
